(19) United States
(12) Patent Application Publication
(10) Pub. No.: US 2009/0096079 A1
(43) Pub. Date: Apr. 16, 2009

(54) SEMICONDUCTOR PACKAGE HAVING A WARPAGE RESISTANT SUBSTRATE

(76) Inventor: Myung Geun PARK, Seoul (KR)

Correspondence Address: LADAS & PARRY LLP, 224 SOUTH MICHIGAN AVENUE, SUITE 1600, CHICAGO, IL, 60604, US

(21) Appl. No.: 12/044,123

(22) Filed: Mar. 7, 2008

(30) Foreign Application Priority Data
Oct. 10, 2007 (KR) 10-2007-0102252

(51) Int. Cl. H01L 23/48

(52) U.S. Cl. 257/690; 257/E23.031

(57) ABSTRACT

A semiconductor package is presented having a substrate, a semiconductor chip, an under-fill material, and a solder resist pattern. The substrate having a substrate body, wiring lines which are located on a first surface of the substrate body and which have connection pad parts, and ball lands which are located on a second surface of the substrate body, facing away from the first surface, and which are electrically connected with the wiring lines. The semiconductor chip having bumps which are electrically connected with the respective connection pad parts. The under-fill material filling a space between the substrate and the semiconductor chip. The solder resist pattern is located on the first surface and has first openings which expose the connection pad parts and has at least one second opening which exposes a portion of the substrate body to provide an enhancement of adhesion force between the under-fill material and the substrate body.

### CROSS-REFERENCE TO RELATED APPLICATIONS

The present application claims priority to Korean patent application number 10-2007-0102252 filed on Oct. 10, 2007, which is incorporated herein by reference in its entirety.

### BACKGROUND OF THE INVENTION

The present invention relates to a semiconductor package.

Recently, semiconductor packages having semiconductor devices suitable for processing a large amount of data in a short time have been developed.

Semiconductor packages are manufactured through a semiconductor chip manufacturing process for forming semiconductor chips on a wafer made of silicon having high purity, a die sorting process for electrically inspecting the semiconductor chips, and a packaging process for packaging parted semiconductor chips.

A recently developed semiconductor package such as a chip scale package has a size which is no greater than 100% to 105% of the size of a semiconductor chip. A flip chip package as a kind of chip scale package has a structure in which the bumps formed on the bonding pads of a semiconductor chip are directly connected with the connection pads exposed through the solder resist formed on a substrate.

In the case of the flip chip package, since the connection pads of the substrate and the bumps of the semiconductor chip are directly connected with each other, a space is defined between the substrate and the semiconductor chip. In this regard, a conventional flip chip package includes an under-fill material which is interposed between the substrate and the semiconductor chip.

However, the conventional flip chip package suffers from defects in that the under-fill material and the solder resist are likely to peel off due to the presence of moisture and the like, and thereby, the bumps of the semiconductor chip and the connection pads of the substrate are likely to be disconnected from each other.

### SUMMARY OF THE INVENTION

Embodiments of the present invention are directed to a semiconductor package which prevents a solder resist and an under-fill material being in contact with the solder resist from peeling off, thereby improving the reliability thereof.

In one aspect, a semiconductor package comprises a substrate having a substrate body, wiring lines which are located on a first surface of the substrate body and have connection pad parts, and ball lands which are located on a second surface of the substrate body, facing away from the first surface, and are electrically connected with the wiring lines; a semiconductor chip having bumps which are electrically connected with the respective connection pad parts; an under-fill material filling a space between the substrate and the semiconductor chip; and a solder resist pattern located on the first surface and having first openings which expose the connection pad parts and at least one second opening which exposes a portion of the substrate body to increase adhesion force between the under-fill material and the substrate body.

The second opening may have a stripe shape when viewed from the top.

The second opening may also have either a circle shape or a polygon shape when viewed from the top.

A plurality of second openings may also be arranged in a pattern having a matrix shape.

The second opening may also have a so-called lattice shape.

The semiconductor package may further comprises oxidation prevention layers covering the wiring lines exposed through the second opening.

The oxidation prevention layers comprise a gold-plated layer and a nickel-plated layer.

The semiconductor package further comprises an additional solder resist pattern located on the second surface to expose the ball lands.

By adjusting an area of the second opening defined through the solder resist pattern located on the first surface, a first effective surface area of the solder resist pattern can be made to become substantially the same as a second effective surface area of the additional solder resist pattern.

The semiconductor package may further comprises solders interposed between the connection pad parts and the bumps.

### BRIEF DESCRIPTION OF THE DRAWINGS

FIG. 1 is a cross-sectional view illustrating a semiconductor package in accordance with a first embodiment of the present invention.

FIG. 2 is a plan view illustrating the substrate shown in FIG. 1.

FIG. 3 is a plan view illustrating the substrate of a semiconductor package in accordance with a second embodiment of the present invention.

FIG. 4 is a plan view illustrating the substrate of a semiconductor package in accordance with a third embodiment of the present invention.

FIG. 5 is a plan view illustrating the substrate of a semiconductor package in accordance with a fourth embodiment of the present invention.

FIG. 6 is a cross-sectional view taken along the line I-I′ of FIG. 5.

### DESCRIPTION OF SPECIFIC EMBODIMENTS

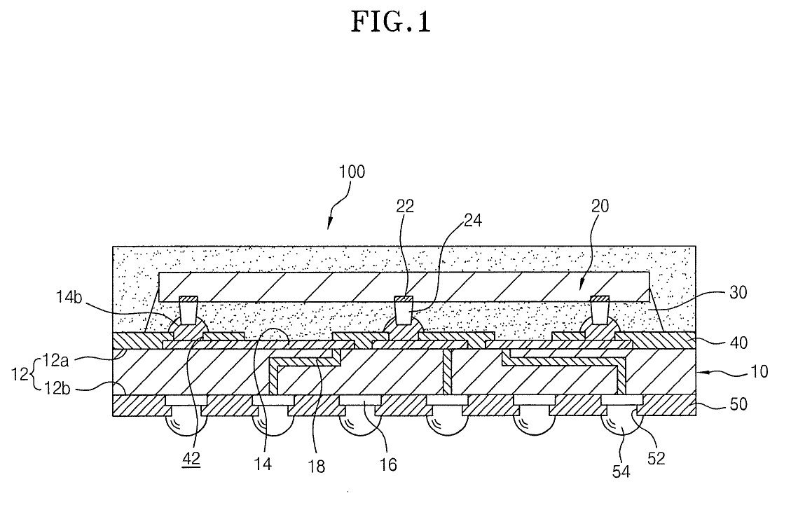

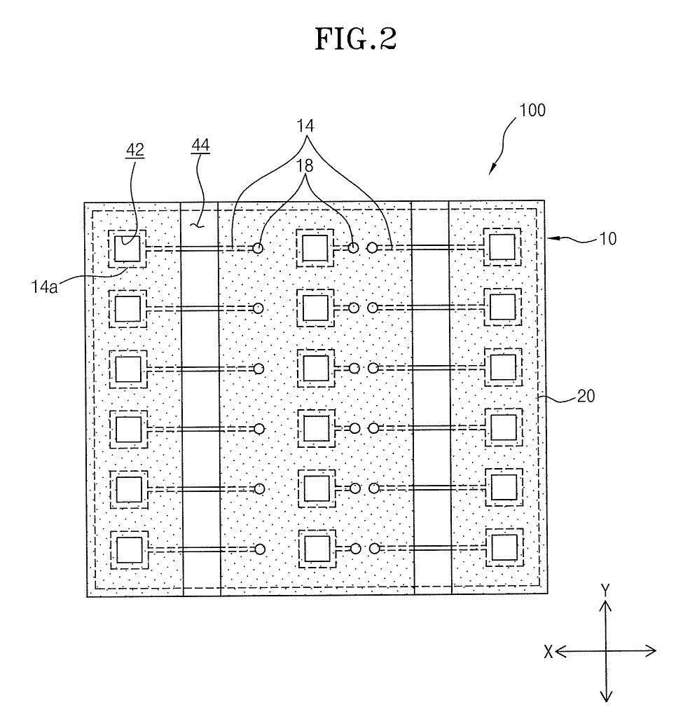

FIG. 1 is a cross-sectional view illustrating a semiconductor package in accordance with a first embodiment of the present invention. FIG. 2 is a plan view illustrating the substrate shown in FIG. 1.

Referring to FIGS. 1 and 2, a semiconductor package 100 includes a substrate 10, a semiconductor chip 20, an under-fill member 30, and a solder resist pattern 40 having first openings 42 and second openings 44.

The substrate 10 includes a substrate body 12, wiring lines 14, and ball lands 16. In the present embodiment, the substrate 10 can, for example, be a printed circuit board.

The substrate body 12 has, for example, the shape of a plate. The substrate body 12 having the shape of a plate has a first surface 12a and a second surface 12b which faces away from the first surface 12a.

The wiring lines 14 are located on the first surface 12a of the substrate body 12. The wiring lines 14 have the shape of a line. Connection pad parts 14a are formed at the ends of the wiring lines 14 having the shape of a line.

In the present embodiment, the materials of the wiring lines 14 can include copper, copper alloys, aluminum, and aluminum alloys. These materials can be used independently or in a mixed state.

For example, contacting members 14b are electrically connected to the connection pad parts 14a of the wiring lines 14. The contacting members 14b, for example, include a metal with a low melting point. For example,

The ball lands 16 are located on the second surface 12b of the substrate body 12. The ball lands 16 are located, for example, in the type of a matrix. The respective ball lands 16 are electrically connected with the wiring lines 14 by the medium of conductive vias 18 which are formed in the substrate body 12.

The semiconductor chip 20 is located over the first surface 12a of the substrate body 12. The semiconductor chip 20 includes bonding pads 22 and bumps 24.

The bonding pads 22 are located on one surface of the semiconductor chip 20 which faces the first surface 12a of the substrate body 12. For example, the respective bonding pads 22 are located at positions which correspond to the connection pad parts 14a located on the first surface 12a of the substrate body 12.

The bumps 24 are respectively connected to the bonding pads 22. In the present embodiment, gold can be used as the material of the bumps 24. The bumps 24 are located on the respective bonding pads 22 while having the shape of a protuberance.

The bumps 24 of the semiconductor chip 20 are electrically connected with the contacting members 14b which cover the connection pad parts 14a of the respective wiring lines 14 formed on the substrate body 12.

The under-fill member 30 is interposed between the semiconductor chip 20 and the first surface 12a of the substrate body 12. The under-fill member 30 secures the semiconductor chip 20 to the substrate body 12 and increases the connection force between the bumps 24 of the semiconductor chip 20 and the connection pad parts 14a of the wiring lines 14 located on the substrate body 12. In addition, the under-fill member 30 prevents outside moisture and air from leaking between the semiconductor chip 20 and the substrate body 12.

The solder resist pattern 40 is interposed between the under-fill member 30 and the substrate body 12. In the present embodiment, the solder resist pattern 40 is located on the first surface 12a of the substrate body 12. The solder resist pattern 40 contains an insulation material and prevents the wiring lines 14 formed on the first surface 12a of the substrate body 12 from being electrically short-circuited by other conductive members.

The solder resist pattern 40 has the first openings 42 and the second openings 44.

The first openings 42 of the solder resist pattern 40 have the shape of an island when viewed from the top. The first openings 42 having the shape of an island selectively expose the connection pad parts 14a of the wiring lines 14 which are located on the first surface 12a of the substrate body 12. The bumps 24 of the semiconductor chip 20 are electrically connected with the connection pad parts 14a through the first openings 42 of the solder resist pattern 40.

The second openings 44 of the solder resist pattern 40 have the shape of a stripe when viewed from the top. For example, at least one second opening 44 having the shape of a stripe is defined along the Y-axis in FIG. 2. Unlike this, the second openings 44 can be defined along the X-axis in FIG. 2.

By the second openings 44 of the solder resist pattern 40, having the shape of a stripe, the under-fill member 30 adheres not only to the solder resist pattern 40 but also to the substrate body 12 and/or the wiring lines 14, so that the adhesion force among the under-fill member 30, the solder resist pattern 40 and the substrate 10 significantly increases. As the adhesion force between the under-fill member 30 and the solder resist pattern 40 increases, it is possible to prevent moisture from leaking between the semiconductor chip 20 and the substrate body 12 and to prevent the under-fill member 30 and the solder resist pattern 40 from peeling off.

Meanwhile, an additional solder resist pattern 50, which has openings 52 for exposing the ball lands 16, is located on the second surface 12b of the substrate 10. Conductive balls 54 such as solder balls are electrically connected to the ball lands 16.

In the present embodiment, the effective surface area of the additional solder resist pattern 50 having the openings 52 is substantially the same as the effective surface area of the solder resist pattern 40 having the first and second openings 42 and 44. In the present embodiment, by adjusting the open area of the second openings 44, the effective surface area of the solder resist pattern 40 becomes substantially the same as the effective surface area of the additional solder resist pattern 50. If the effective surface area of the solder resist pattern 40 and the effective surface area of the additional solder resist pattern 50 are substantially the same, the warpage of the substrate 10 can be prevented or at least minimized.

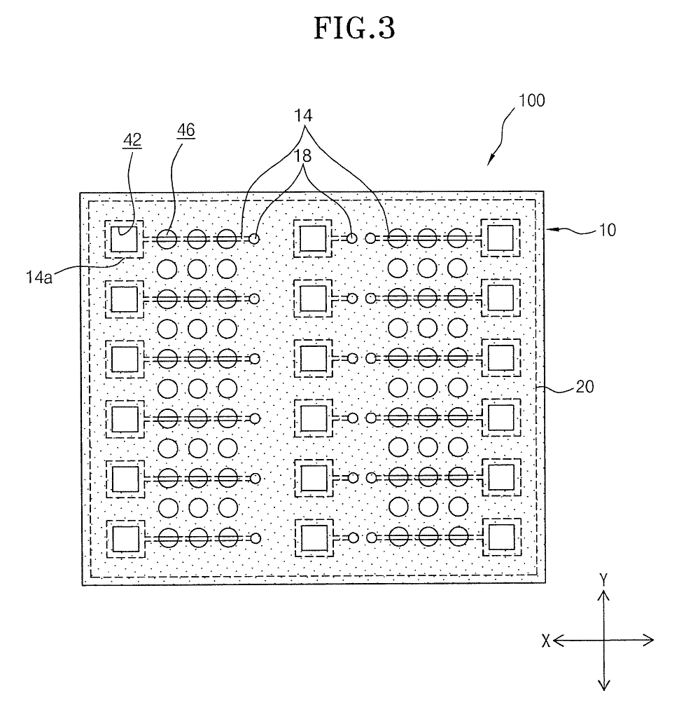

FIG. 3 is a plan view illustrating the substrate of a semiconductor package in accordance with a second embodiment of the present invention. The semiconductor package in accordance with the second embodiment of the present invention is substantially the same as that of the aforementioned first embodiment, except a solder resist pattern. Therefore, description for the same parts will be omitted herein, and the same terms and the same reference numerals will be used to refer to the same parts.

Referring to FIGS. 1 and 3, the solder resist pattern 40 of a semiconductor package 100 is interposed between an under-fill member 30 and a substrate body 12. In the present embodiment, the solder resist pattern 40 is located on the first surface 12a of the substrate body 12. The solder resist pattern 40 contains an insulation material and prevents the wiring lines 14 formed on the first surface 12a of the substrate body 12 from being electrically short-circuited by other conductive members.

The solder resist pattern 40 has first openings 42 and second openings 46.

The first openings 42 of the solder resist pattern 40 have the shape of an island when viewed from the top. The first openings 42 having the shape of an island selectively expose the connection pad parts 14a of the wiring lines 14 which are located on the first surface 12a of the substrate body 12. The bumps 24 of a semiconductor chip 20 are electrically connected with the connection pad parts 14a through the first openings 42 of the solder resist pattern 40.

The second openings 46 of the solder resist pattern 40 have the shape of a circle when viewed from the top. For example, at least one second opening 46 having the shape of a circle is defined through the solder resist pattern 40. In the present embodiment, the second openings 46 having the shape of a circle can be defined through the solder resist pattern 40, for example, in a plural number and in the type of a matrix. In the present embodiment, the areas of the respective second openings 46 can be the same. Also, in the present embodiment, the second openings 46 can have a variety of shapes such as a triangle, a quadrangle and a polygon. Further, in the present embodiment, the solder resist pattern 40 can be irregularly located when viewed from the top.

By the second openings 46 of the solder resist pattern 40, having the shape of a circle, the under-fill member 30 adheres not only to the solder resist pattern 40 but also to the substrate body 12 and/or the wiring lines 14, so that the adhesion force among the under-fill member 30, the solder resist pattern 40 and the substrate 10 significantly increases. As the adhesion force between the under-fill member 30 and the solder resist pattern 40 increases, it is possible to prevent moisture from leaking between the semiconductor chip 20 and the substrate body 12 and to prevent the under-fill member 30 and the solder resist pattern 40 from peeling off.

Meanwhile, an additional solder resist pattern 50, which has openings 52 for exposing the ball lands 16, is located on the second surface 12b of the substrate 10. Conductive balls 54 such as solder balls are electrically connected to the ball lands 16.

In the present embodiment, the effective surface area of the additional solder resist pattern 50 having the openings 52 is substantially the same as the effective surface area of the solder resist pattern 40 having the first and second openings 42 and 46. In the present embodiment, by adjusting the open area of the second openings 46, the effective surface area of the solder resist pattern 40 becomes substantially the same as the effective surface area of the additional solder resist pattern 50. If the effective surface area of the solder resist pattern 40 and the effective surface area of the additional solder resist pattern 50 are substantially the same, the warpage of the substrate 10 can be prevented or minimized.

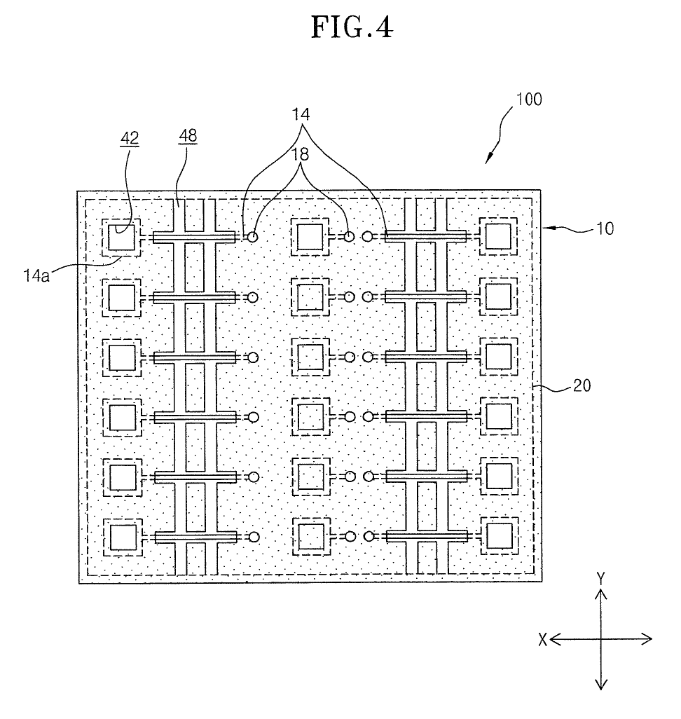

FIG. 4 is a plan view illustrating the substrate of a semiconductor package in accordance with a third embodiment of the present invention. The semiconductor package in accordance with the third embodiment of the present invention is substantially the same as that of the aforementioned first embodiment, except a solder resist pattern. Therefore, description for the same parts will be omitted herein, and the same terms and the same reference numerals will be used to refer to the same parts.

Referring to FIGS. 1 and 4, the solder resist pattern 40 of a semiconductor package 100 is interposed between an under-fill member 30 and a substrate body 12. In the present embodiment, the solder resist pattern 40 is located on the first surface 12a of the substrate body 12. The solder resist pattern 40 contains an insulation material and prevents the wiring lines 14 formed on the first surface 12a of the substrate body 12 from being electrically short-circuited by other conductive members.

The solder resist pattern 40 has first openings 42 and second openings 48.

The first openings 42 of the solder resist pattern 40 have the shape of an island when viewed from the top. The first openings 42 having the shape of an island selectively expose the connection pad parts 14a of the wiring lines 14 which are located on the first surface 12a of the substrate body 12. The bumps 24 of a semiconductor chip 20 are electrically connected with the connection pad parts 14a through the first openings 42 of the solder resist pattern 40.

The second openings 48 of the solder resist pattern 40 have the shape of a lattice when viewed from the top.

By the second openings 48 of the solder resist pattern 40, having the shape of a lattice, the under-fill member 30 adheres not only to the solder resist pattern 40 but also to the substrate body 12 and/or the wiring lines 14, so that the adhesion force among the under-fill member 30, the solder resist pattern 40 and the substrate 10 significantly increases. As the adhesion force between the under-fill member 30 and the solder resist pattern 40 increases, it is possible to prevent moisture from leaking between the semiconductor chip 20 and the substrate body 12 and to prevent the under-fill member 30 and the solder resist pattern 40 from peeling off.

Meanwhile, an additional solder resist pattern 50, which has openings 52 for exposing the ball lands 16, is located on the second surface 12b of the substrate 10. Conductive balls 54 such as solder balls are electrically connected to the ball lands 16.

In the present embodiment, the effective surface area of the additional solder resist pattern 50 having the openings 52 is substantially the same as the effective surface area of the solder resist pattern 40 having the first and second openings (42 and 48, respectively). In the present embodiment, by adjusting the open area of the second openings 48, the effective surface area of the solder resist pattern 40 becomes substantially the same as the effective surface area of the additional solder resist pattern 50. If the effective surface area of the solder resist pattern 40 and the effective surface area of the additional solder resist pattern 50 are substantially the same, the warpage of the substrate 10 can be prevented or minimized.

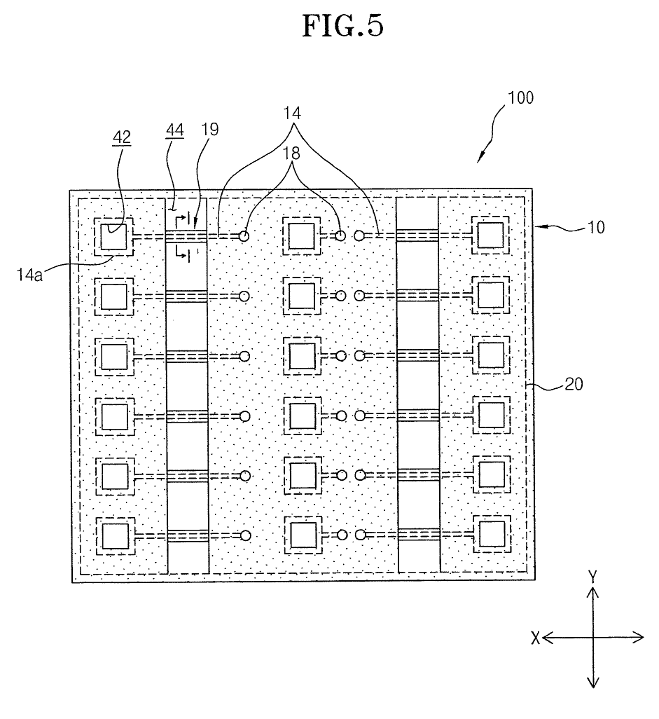

FIG. 5 is a plan view illustrating the substrate of a semiconductor package in accordance with a fourth embodiment of the present invention.

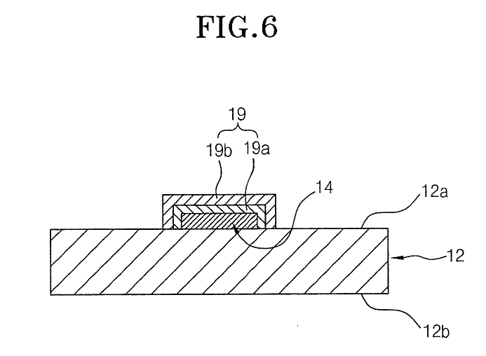

FIG. 6 is a cross-sectional view taken along the line I-I′ of FIG. 5. The semiconductor package in accordance with the fourth embodiment of the present invention is substantially the same as that of the aforementioned first embodiment, except an oxidation prevention layer. Therefore, description for the same parts will be omitted herein, and the same terms and the same reference numerals will be used to refer to the same parts.

Referring to FIGS. 1, 5 and 6, portions of the wiring lines 14, which are located on the first surface 12a of the substrate body 12, are exposed through the second openings 44 of the solder resist pattern 40. In the present embodiment, when the wiring lines 14 contain copper and the like, which is rapidly oxidated in the atmosphere, the wiring lines 14 are likely to be oxidated, and thereby, the electrical characteristics of the wiring lines 14 can be deteriorated.

In order to cope with this problem, oxidation prevention layers 19 are formed on the wiring lines 14 which are exposed through the second openings 44. In the present embodiment, the oxidation prevention layers 19 can, for example, be plated layers. For example, the oxidation prevention layer 19 can include a nickel-plated layer 19a and a gold-plated layer 19b.

As is apparent from the above description, in the present invention, openings are defined through portions of a solder resist pattern, which are different from the portions where connection pad parts are formed on a substrate, such that an under-fill member can firmly adhere to the substrate, the solder resist pattern and wiring lines, whereby it is possible to prevent the under-fill member and the solder resist pattern from peeling off.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor package comprising:
a substrate having a substrate body, wiring lines located on a first surface of the substrate body and which have connection pad parts, and ball lands located on a second surface of the substrate body, facing away from the first surface, and which are electrically connected with the wiring lines;
a semiconductor chip having bumps electrically connected with the connection pad parts;
an under-fill material filling a space between the substrate and the semiconductor chip; and
a solder resist pattern located on the first surface and having first openings exposing the connection pad parts and at least one second opening exposing a portion of the substrate body wherein allowing an increase in an adhesion force between the under-fill material and the substrate body.

2. The semiconductor package according to claim 1, wherein the second opening has a stripe shape when viewed from the top.

3. The semiconductor package according to claim 1, wherein the second opening has either a circle shape or a polygon shape when viewed on a plane.

4. The semiconductor package according to claim 3, wherein the solder resist pattern has a plurality of second openings in a matrix shape.

5. The semiconductor package according to claim 1, wherein the second opening has a lattice shape.

6. The semiconductor package according to claim 1, further comprising:
oxidation prevention layers covering the wiring lines exposed through the second opening.

7. The semiconductor package according to claim 1, wherein the oxidation prevention layers comprise a gold-plated layer and/or a nickel-plated layer.

8. The semiconductor package according to claim 1, further comprising:
an additional solder resist pattern located on the second surface exposing the ball lands.

9. The semiconductor package according to claim 8, wherein an area of the second opening defined through the solder resist pattern located on the first surface is adjusted such that a first effective surface area of the solder resist pattern becomes substantially the same as a second effective surface area of the additional solder resist pattern.

10. The semiconductor package according to claim 1, further comprising:
contacting members interposed between the connection pad parts and the bumps.
